(19) United States
(12) Patent Application Publication
(10) Pub. No.: US 2025/0231401 A1
(43) Pub. Date: Jul. 17, 2025

(54) OPTICAL ELEMENT, METHOD FOR MAKING THE OPTICAL ELEMENT, AND HEAD-MOUNTED DEVICE

(71) Applicants: Asphetek Solution (Chengdu) Ltd., Chengdu (CN); ADVANCED OPTOELECTRONIC TECHNOLOGY, INC., Hsinchu County (TW); Asphetek Solution Inc., Hsinchu (TW)

(72) Inventors: CHEN-AN CHIANG, Hsinchu (TW); Chung-Wu LIU, Hsinchu (TW); I-Ming CHENG, Hsinchu (TW); Yi-Huan CHOU, Hsinchu (TW)

(21) Appl. No.: 18/646,628

(22) Filed: Apr. 25, 2024

(30) Foreign Application Priority Data
Jan. 16, 2024 (CN) 202410068279.0

(51) Int. Cl. G02B 27/00; G02B 27/01

(52) U.S. Cl. CPC G02B 27/0093; G02B 27/0172; G02B 2027/0178

(57) ABSTRACT

An optical element includes a substrate layer and a reflection element circular shaped on a surface of the substrate layer. The reflection element includes a base and a plurality of reflection structures protruding from the base to a direction away from the substrate layer. Each reflection structure includes an incident surface and an exit surface. The incident surface is configured to transmit a portion of a signal light and reflect another portion of the signal light. The exit surface is configured to transmit the portion of the signal light from the incident surface to a next incident surface, making the portion of the signal light transmit in the plurality of reflection structures successively, and making another portion of the signal light exit away from the substrate layer. A method for making an optical element and a head-mounted device are also provided.

### FIELD

The subject matter herein generally relates to eye tracking, and particularly relates to an optical element, method for making the optical element, and a head-mounted device.

### BACKGROUND

Eye tracking devices for head mounted apparatuses (such as virtual reality glasses) mainly includes a waveguide and multiple light emitting diodes (LEDs) or vertical cavity surface emitting lasers (VCSELs). The LEDs and the VCSELs are used to emit light to the user's eyes. The LEDs and the VCSELs are connected to the waveguide through multiple bonding processes, which increases an anomalies risk when making the eye tracking devices.

Therefore, there is room for improvement within the art.

### BRIEF DESCRIPTION OF THE DRAWINGS

Implementations of the present disclosure will now be described, by way of embodiment, with reference to the attached figures, wherein:

FIG. 1 shows an optical element in an embodiment of the present disclosure.

FIG. 2 shows a cross-sectional structure of the optical element in the embodiment of the present disclosure along line II-II.

FIG. 3 is a schematic view of a path of a signal light in the reflection element of FIG. 1.

FIG. 4 is a partial view of the reflection element on a surface of a substrate layer in a first embodiment.

FIG. 5 is a schematic view of a path of the signal light in the reflection element of the first embodiment.

FIG. 6 is a partial view of the reflection element on the surface of the substrate layer in a second embodiment.

FIG. 7 is a schematic view of a path of the signal light in the reflection element of the second embodiment.

FIG. 8 is a partial view of the reflection element on the surface of the substrate layer in a third embodiment.

FIG. 9 is a schematic view of a path of the signal light in the reflection element of the third embodiment.

FIG. 10 is a partial view of a head mounted device according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “comprising,” when utilized, means “including, but not necessarily limited to”; it specifically indicates open-ended inclusion or membership in the so-described combination, group, series, and the like.

“Above” means one layer is on top of another layer. In one example, it means one layer is situated directly on top of another layer. In another example, it means one layer is situated over the second layer directly or indirectly with more layers or spacers in between.

When a feature or element is herein referred to as being “on” another feature or element, it can be directly on the other feature or element or intervening features and/or elements may also be present. It will also be understood that, when a feature or element is referred to as being “connected”, “attached” or “coupled” to another feature or element, it can be directly connected, attached, or coupled to the other feature or element or an intervening features or elements may be present.

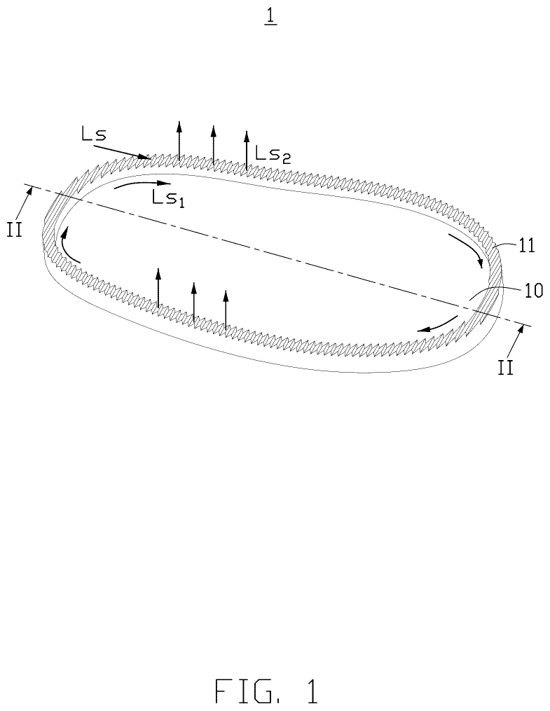

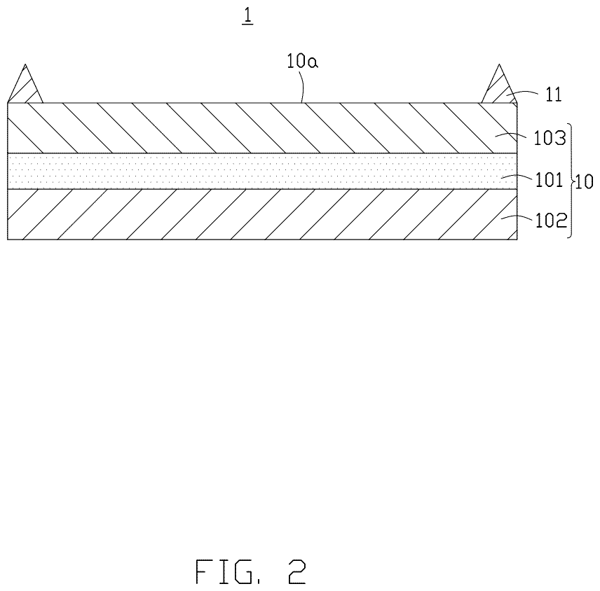

As shown in FIG. 1 and FIG. 2, an optical element 1 of the present embodiment includes a substrate layer 10 and a reflection element 11 on a surface of the substrate layer 10, wherein the reflection element 11 is in a circular shape. The substrate layer 10 includes an adhesive layer 101, a transparent layer 102, and a transparent waveguide layer 103. The adhesive layer 101 is between the transparent layer 102 and the transparent waveguide layer 103, and the reflection element 11 is on a surface of the transparent waveguide layer 103 away from the adhesive layer 101.

The substrate layer 10 is used to receive and transmit external environmental light, and the adhesive layer 101 is used to adhere the transparent layer 102 to the surface of the transparent waveguide layer 103 away from the reflection element 11.

The adhesive layer 101 may be an optically clear adhesive (OCA).

The transparent layer 102 may be a transparent flat lens, a transparent myopia lens, or a transparent hyperopia lens. The transparent flat lens is suitable for users with normal vision, the transparent myopia lens is suitable for users with myopia, and the transparent hyperopia lens is suitable for users with hyperopia. According to different usage needs, Different transparent lenses fit different user's needs, which can improve an effective of the optical element 1. The transparent layer 102 may be made of plastic or glass. The transparent layer 102 is fixed to the transparent waveguide layer 103 through the adhesive layer 101 and is used to receive the external environmental light and transmit the external environmental light to the transparent waveguide layer 103.

The transparent waveguide layer 103 may be a waveguide plate and is used to transmit the ambient light to human eye 3.

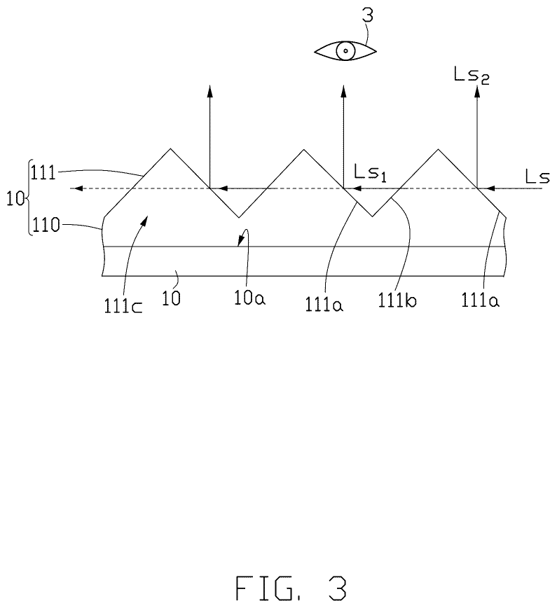

The reflection element 11 may be formed on a surface 10a of the substrate layer 10 through nanoimprinting technology. In this embodiment, the surface 10a is the surface of the transparent waveguide layer 103 away from the adhesive layer 101. As shown in FIG. 3, the reflection element 11 includes a circular base 110 and a plurality of reflection structures 111 protruding from the base 110 in a direction away from the substrate layer 10, and the reflection structures 111 are arranged in an array. The reflection structures 111 are arranged sequentially along a circular direction of the base 110. Each reflection structure 111 includes an incident surface 111a, an exit surface 111b, and two side surfaces 111c. The incident surface 111a and the exit surface 111b are between the two side surfaces 111c and intersect with the two side surfaces 111c.

The incident surface 111a is used to receive and transmit a portion of a signal light L_{S}, so that the portion of the signal light L_{S} can transmit through the exit surface 111b to an incident surface 111a of a next reflection structure 111 as a first light Lₛ₁. The first light Lₛ₁ passes through the reflection structures 111 of the reflection element 11 along the circular direction. The incident surface 111a is also used to reflect another portion of the signal light L_{S}. Another portion of the signal light L_{S} reflected by the incident surface 111a exit away from the substrate layer 10 as a second light Lₛ₂.

The optical element 1 may be used in a head mounted device as a window corresponding to the user's eye. For example, the optical element 1 may be a lens for a left or right eye), and the reflection element 11 is on a side of the optical element 1 facing the user's eye, wherein the second light L_{S2} can be transmitted to the user's eye 3, so that movement characteristics of the eyeball can be obtained based on the second light L_{S2}.

The reflection structures 111 can be arranged in multiple different ways.

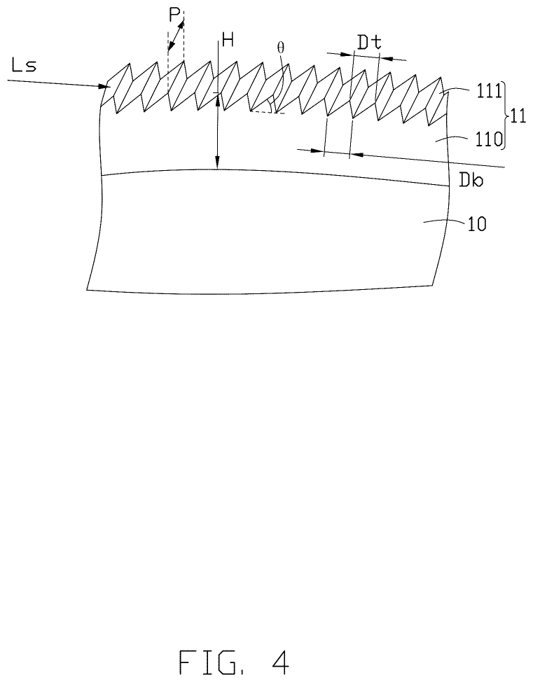

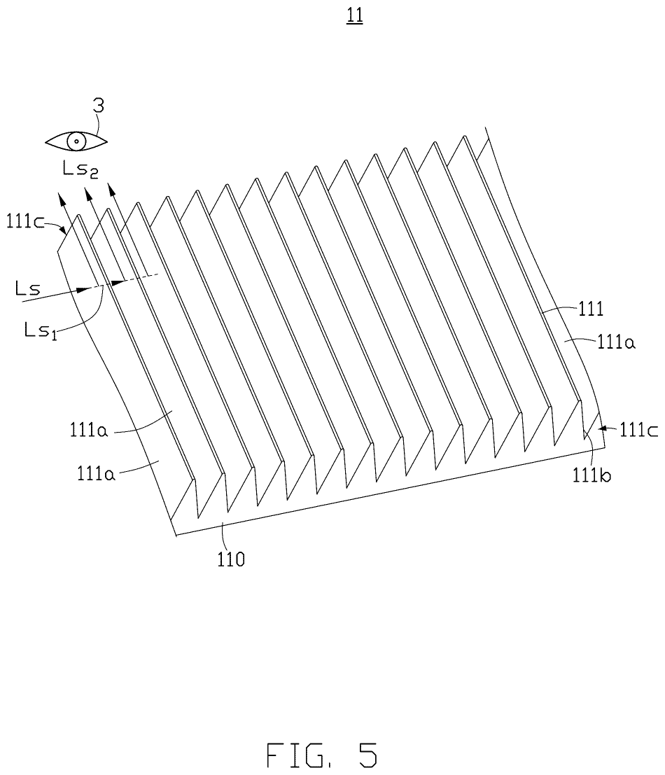

As shown in FIG. 4 and FIG. 5, in a first embodiment, each of the reflection structure 111 is serrated shaped. The reflective structures 111 are arranged sequentially along the circular direction of the base 110. Each reflection structure 111 includes the incident surface 111a, the exit surface 111b, and two side surfaces 111c. The two side surfaces 111c are spaced apart and roughly parallel to each other. The incident surface 111a and exit surface 111b are between and intersect with the two side surfaces 111c. The incident surface 111a and exit surface 111b intersect at the top of the reflection structure 111 away from the base 110. An edge of each incident surface 111a near the base 110 is connected to an edge of the exit surface 111b near the base 110 in an adjacent reflection structure 111.

An extension direction (or length direction) of the reflection structure 111 is defined as a direction from one side surface 111c to the other side surface 111c. The extension directions of the reflection structures 111 do not intersect vertically (intersect obliquely) with the circular direction of the reflective element 11.

As shown in FIG. 4, an angle between each incident surface 111a and the surface 10a of the substrate layer 10 is in a range of 100-80°, and an angle between each exit surface 111b and the surface 10a of the substrate layer 10 is in a range of 100-80°. A height H from a top of each reflection structure 111 to the surface 10a of the substrate layer 10 is in a range of 20 nm-500 μm. A width Db of a widest position of each reflection structure 111 along the extension direction of the reflection element 11 is in a range of 20 nm-500 μm. A distance Dt between the top of two adjacent reflection structures 111 is in a range of 1 μm-15 cm. A distance P (i.e. length) between the two side surfaces 111c in each reflection structure 111 is in a range of 20 nm-500 μM.

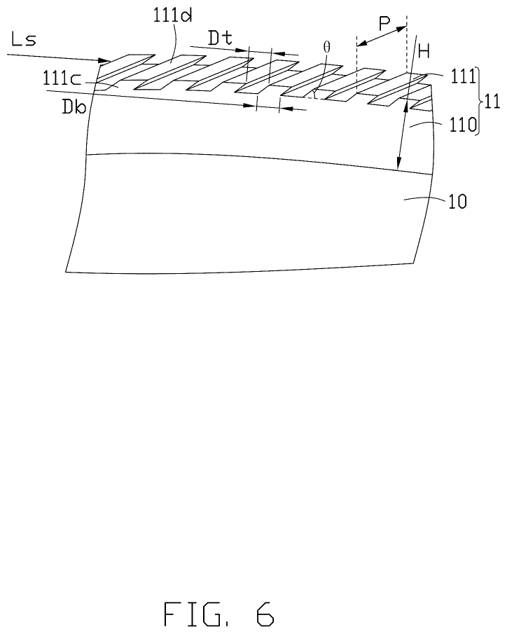

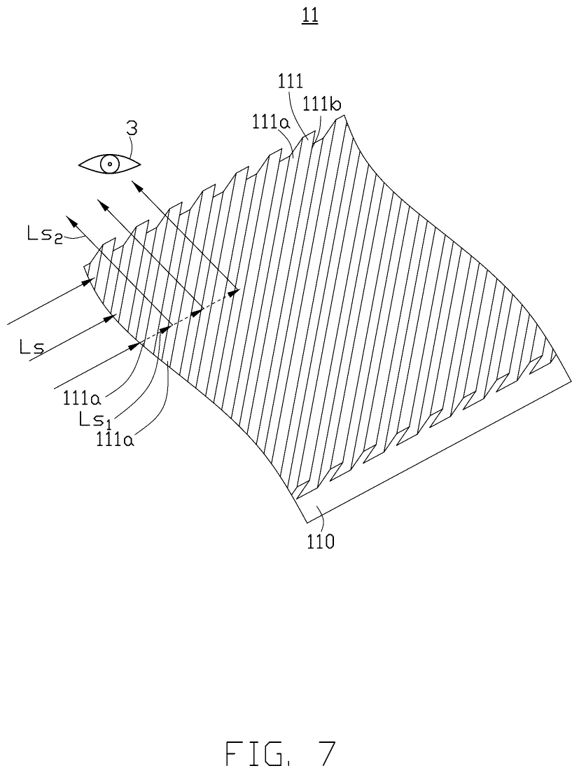

As shown in FIG. 6 and FIG. 7, in a second embodiment, each of the reflection structure 111 is straight-bar shaped. The reflective structures 111 are arranged sequentially along the circular direction of the base 110. Each reflection structure 111 includes the incident surface 111a, the exit surface 111b, two side surfaces 111c, and a flat surface 111d parallel to the surface 10a. The two side surfaces 111c are roughly parallel to each other and intersect with the flat surface 111d. The incident surface 111a and exit surface 111b are between and intersect with the two side surfaces 111c. The incident surface 111a and exit surface 111b are between the flat surface 111d and the base 110 and intersect with the flat surface 111d.

As shown in FIG. 6, an angle between each incident surface 111a and the surface 10a of the substrate layer 10 is in a range of 10°-80°, and an angle between each exit surface 111b and the surface 10a of the substrate layer 10 is in a range of 10°-80°. A height H from a top of each reflection structure 111 to the surface 10a of the substrate layer 10 is in a range of 20 nm-500 μm. A width Db of a widest position of each reflection structure 111 along the extension direction of the reflection element 11 is in a range of 20 nm-500 μm. That is, in each reflection structure 111, a width Db between an edge of the incident surface 111a near the surface 10a and an edge of the exit surface 111b near the surface 10a is in a range of 20 nm-500 μm. A distance Dt between the top of two adjacent reflection structures 111 is in a range of 1 μm-15 cm. A distance P (i.e. length) between the two side surfaces 111c in each reflection structure 111 is in a range of 20 nm-500 μM.

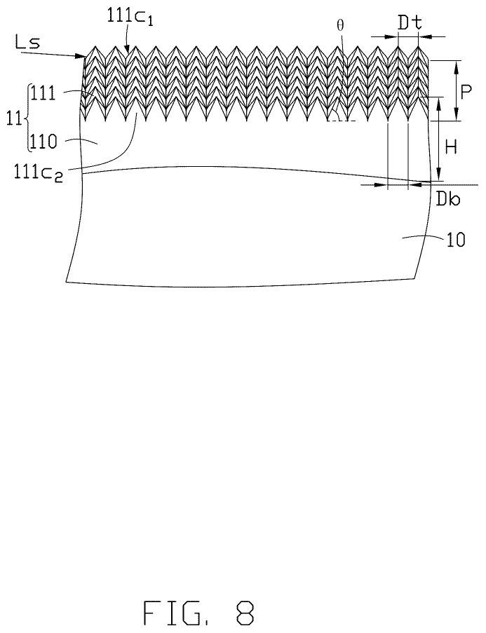

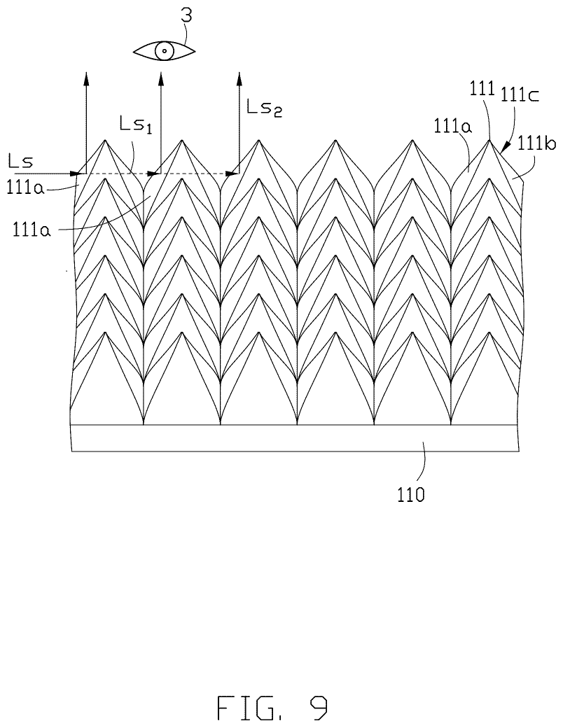

As shown in FIG. 8 and FIG. 9, in a third embodiment, each reflection structure 111 is pyramid shaped (That is, each reflection structure 111 comprises a sharp point). The reflective structures 111 are arranged in an array along the circular direction of the base 110, and the reflective structures 111 are perpendicular to the circular direction. Each reflection structure 111 includes four oblique surfaces intersect on the vertex (That is, the sharp point) of the reflection structure 111. Two of the four oblique surfaces intersect with the circular direction are defined as the incident surface 111a and the exit surface 111b, and the other two oblique surface parallel to the circular direction are defined as the two side surfaces 111c. An edge of each incident surface 111a near the base 110 is connected to an edge of the exit surface 111b near the base 110 in an adjacent reflection structure 111, and an edge of each side surface 111a near the base 110 is connected to an edge of the side surface 111c near the base 110 in an adjacent reflection structure 111.

As shown in FIG. 8, an angle between each incident surface 111a and the surface 10a of the substrate layer 10 is in a range of 100-80°, and an angle between each exit surface 111b and the surface 10a of the substrate layer 10 is in a range of 10°-80°. A height H from a top of each reflection structure 111 to the surface 10a of the substrate layer 10 is in a range of 20 nm-500 μm. A width Db of a widest position of each reflection structure 111 along the extension direction of the reflection element 11 is in a range of 20 nm-500 μm. A distance Dt between the top of two adjacent reflection structures 111 is in a range of 1 μm-15 cm. In a direction perpendicular to the circular direction, the maximum width P of the reflective element 11 is in a range of 20 nm-500 μM. That is, side surfaces closest to edges of the base 110 are defined as a side surface 111c₁ and a side surface 111c₂. A maximum width P between an edge of the side surface 111c₁ near the base 110 and an edge of the side surface 111c₂ near the base 110 is in a range of 20 nm-500 μM.

The optical element 1 of the present embodiment is used to project light into the user's eye 3 to obtain the movement characteristic of the user's eye 3. The substrate layer 10 of the optical element 1 is used to receive and transmit the ambient light, allowing the user's eye 3 to perceive changes in the external environment based on the ambient light. The reflection element 11 is used to transmit and reflect the signal light L_{S}. A portion of the signal light L_{S} is transmitted through the incident surface 111a as the first light L_{S1} to a next incident surface 111a, and another portion of the signal light L_{S} is reflected by the incident surface 111a as the second light L_{S2} to the user's eye 3. That is, the incident signal light L_{S} transmits through the reflection structures 111 of the reflection element 11 sequentially, and the portion of the signal light L_{S} can be reflected by the incident surfaces 111a and projected as the second light Lₛ₂ to the user's eye 3, so that the movement characteristics of the eyeball can be obtained. A portion of the signal light L_{S} is reflected by the incident surfaces 111a of the reflection element 11, so that the intensity of the signal light L_{S} decays gradually when the signal light L_{S} passes through the reflection element 11. In this embodiment, the reflection element 11 further includes a light source 22 on a bending area to improve an intensity decay of the signal light L_{S}.

A method for making the above-mentioned optical element 1 includes the following steps:

Step 1, providing an imprinting material on the surface 10a of the substrate layer 10 to form an imprinted layer.

In this embodiment, the imprinting material is a semi-transparent and semi-reflective material, so that the imprinted layer formed of the imprinting material is used for transmitting a portion of the signal light and reflecting another portion of the signal light to change a direction of the signal light. The imprinting material can be a heat cured resin material or a light cured resin material (usually also known as photoresist). For example, the imprinting material can be titanium dioxide (TiO2) or photo sensitive epoxy resin.

In this embodiment, the imprinted layer is formed by coating the imprinting material on the surface 10a of the substrate layer 10. The imprinting material can be coated by spin coating to form a uniform imprinted layer.

Step 2, imprinting a side of the imprinted layer away from the substrate layer 10 to form a nanoimprint pattern including the reflection element 11.

In this embodiment, the imprinting a side of the imprinted layer includes: using a template with features of the reflection element 11 to imprint the side of the imprinted layer away from the substrate layer 10. A surface of the template with the nanoimprint pattern is tightly contacted with the side of the imprinted layer away from the substrate layer 10. The nanoimprint pattern on the template will be transferred to the imprinted layer under pressure.

In this embodiment, the method for making the optical element 1 further includes curing the imprinted layer before separating the template from the imprinted layer. The imprinted layer can be thermal cured or light cured.

In this embodiment, the method further includes forming an anti-adhesion layer on the surface of the template with the nanoimprinted pattern before imprinting the side of the imprinted layer away from the substrate layer 10 by the template. The anti-adhesion layer can prevent the template from sticking to the imprinted layer when separating the template, so that the template is not damaged during demolding and the nanoimprinted pattern copied onto the imprinted layer does not deform, thereby reducing product defects, ensuring and improving product yield, and reducing manufacturing costs.

In this embodiment, the anti-adhesion layer is an alkyl silane layer, and the forming the anti-adhesion layer on the template includes: spin coating alkyl silane gel on the surface of the template with the nanoimprint pattern to form the anti-adhesion layer.

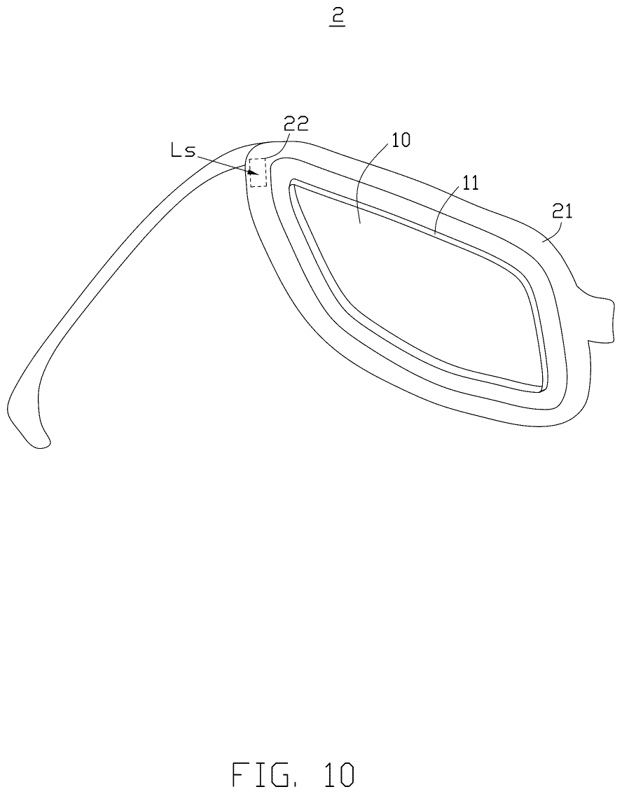

As shown in FIG. 10, a head-mounted device 2 provided in the present embodiment includes a frame 21, a light source 22, and an optical element 1. The light source 22 is used to emit the signal light L_{S} to the optical element 1. The signal light L_{S} is invisible and will not cause harm to eyes 3. In this embodiment, the light source 22 is embedded in the frame 21. In other embodiments, the light source 22 may be integrated into an optical engine of the head mounted device 2, wherein the optical engine can be a digital light processor (DLP). The frame 21 is defined with an installation position, and the optical element 1 is fixedly in the installation position. A surface of the optical element 1 with the reflection element 11 faces the user's eye.

The incident surface 111a of the reflection element 11 is used to receive the signal light L_{S}. A portion of the signal light L_{S} transmits through the incident surface 111a and exit from the exit surface 111b as the first light L_{S1}, wherein the first light L_{S1} from the exit surface 111b incidents on the incident surface 111a of the next reflection structure 111, so that the signal light L_{S} sequentially propagates through all the reflection structures 111 of the reflection element 11. The other portion of the signal light L_{S} is reflected by the incident surface 111a and is transmitted to the eye 3 as the second light L_{S2}. That is, each incident surface 111a is used to receive and reflect a portion of the signal light L_{S} from the previous reflection structure 111 and transmit the other portion of the signal light L_{S} to the eye 3. The movement characteristics of the eyeball can be obtained based on the signal light L_{S} transmitted to the eye 3.

In summary, the embodiments of this disclosure have the following beneficial effects.

For the above-mentioned optical element 1, a circular reflection element 11 is provided on the surface 10a of the substrate layer 10. The reflection element 11 includes a plurality of reflection structures 111 arranged in an array. Each reflection structure 111 includes an incident surface 111a and an exit surface 111b. Each incident surface 111a is used to receive the signal light L_{S}. A portion of the signal light L_{S} can be emitted from the exit surface 111b through the reflection structure 111 and received by the incident surface 111a of the adjacent reflection structure 111, so that the signal light L_{S} can be transmitted through all reflection structures 111 along the circular direction of the reflection element 11. The other portion of the signal light L_{S} can be reflected by each incident surface 111a directed away from the substrate layer and received by the eye 3, wherein the movement characteristics of the eyeball are obtained based on the reflected signal light L_{S}.

The optical element 1 of this disclosure needs one light source 22 to emit signal light L_{S} to the reflection element 11. The signal light L_{S} can be guided to the eye 3 through a transmission and reflection of the reflection structures 111 of the reflection element 11. Therefore, there is no need to use multiple bonding processes to connect the light source 22 with the substrate layer 10, simplifying a method of making the optical element 1 for eye tracking and reducing a risk of process abnormalities.

Finally, it should be noted that the above embodiments are only used to illustrate the technical solution of the present application and not to limit the present application. Although the present application has been described in detail with reference to preferred embodiments, one ordinary skill in the art should understand that the technical solution of the present application can be modified or equivalent replaced without departing from the spirit and scope of the technical solution of the present application.

What is claimed is:

1. An optical element comprising:
a substrate layer; and
a reflection element being circular shaped on a surface of the substrate layer, the reflection element comprising a base and a plurality of reflection structures protruding from the base to a direction away from the substrate layer, each of the plurality of reflection structures comprises an incident surface and an exit surface, the incident surface being configured to transmit a portion of a signal light and reflect another portion of the signal light, the exit surface being configured to transmit the portion of the signal light from the incident surface to a next incident surface, making the portion of the signal light transmit in the plurality of reflection structures successively, and making the another portion of the signal light exit away from the substrate layer.

2. The optical element according to claim 1, wherein the plurality of reflection structures arranged in a circular direction of the base.

3. The optical element according to claim 2, wherein the incident surface intersects with the exit surface.

4. The optical element according to claim 3, wherein each of the plurality of reflection structures further comprises two side surfaces parallel to each other, and the incident surface and the exit surface are between and intersect with the side surfaces.

5. The optical element according to claim 4, wherein each of the plurality of reflection structures is serrated shaped; and
an edge of the incident surface and near the base connects an edge of the exit surface of a next reflection structure and near the base.

6. The optical element according to claim 4, wherein each of the plurality of reflection structures is straight-bar shaped; and
each of the plurality of reflection structures further comprises a flat surface parallel to a plane where the substrate layer is, the two side surfaces are between the flat surface and the base and intersect with the flat surface.

7. The optical element according to claim 4, wherein each of the plurality of reflection structures comprises a sharp point and perpendicular to the circular direction.

8. The optical element according to claim 7, wherein each of the plurality of reflection structures comprises four oblique surfaces intersect on the sharp point, two of the four oblique surfaces intersect with the circular direction are defined as the incident surface and the exit surface, the other two of the four oblique surfaces parallel to the circular direction are defined as the two side surfaces.

9. The optical element according to claim 8, wherein an edge of the incident surface and near the base connects an edge of the exit surface of a next reflection structure and near the base, and an edge of each of the two side surfaces near the base connects an edge of the two side surfaces of a next reflection structure and near the base.

10. A method for making an optical element comprising:
providing an imprinting material on a surface of a substrate layer to form an imprinted layer; and
imprinting a side of the imprinted layer away from the substrate layer to form a nanoimprint pattern of a reflection element;
wherein the reflection element is circular shaped and comprises a base and a plurality of reflection structures protruding from the base to a direction away from the substrate layer, each of the plurality of reflection structures comprises an incident surface and an exit surface, the incident surface is configured to transmit a portion of a signal light and reflect another portion of the signal light, the exit surface is configured to transmit the portion of the signal light from the incident surface to a next incident surface, making the portion of the signal light transmit in the plurality of reflection structures successively, and making the another portion of the signal light exit away from the substrate layer.

11. The method for making an optical element according to claim 10, wherein the providing an imprinting material comprises providing a semi-transparent and semi-reflective imprinting material.

12. The method for making an optical element according to claim 11, wherein the providing a semi-transparent and semi-reflective imprinting material comprises:
providing titanium dioxide or photosensitive epoxy resin as an imprinting material.

13. The method for making an optical element according to claim 10, wherein the imprinting a side of the imprinted layer away from the substrate layer to form a nanoimprint pattern of a reflection element comprises:
imprinting the imprinted layer by a template, making a surface of the template with the nanoimprinted pattern in close contact with the side of the imprinted layer away from the base layer, and applying pressure to the template to transfer the nanoimprinted pattern on the template to the imprinted layer.

14. The method for making an optical element according to claim 13, wherein forming an anti-adhesion layer on the surface of the template is comprised before imprinting a side of the imprinted layer away from the substrate layer.

15. A head-mounted device comprising:
a frame;
a light source on the frame and for emitting a signal light;
an optical element on the frame and on an optical path of the signal light, comprising:
a substrate layer; and
a reflection element being circular shaped on a surface of the substrate layer, the reflection element comprising a base and a plurality of reflection structures protruding from the base to a direction away from the substrate layer, each of the plurality of reflection structures comprises an incident surface and an exit surface, the incident surface being configured to transmit a portion of the signal light and reflect another portion of the signal light, the exit surface being configured to transmit the portion of the signal light from the incident surface to a next incident surface, making the portion of the signal light transmit in the plurality of reflection structures successively, and making the another portion of the signal light exit away from the substrate layer.

16. The head-mounted device according to claim 15, wherein the plurality of reflection structures arranged in a circular direction of the base, and the incident surface intersects with the exit surface

17. The head-mounted device according to claim 16, wherein each of the plurality of reflection structures is serrated shaped, straight-bar shaped, or pyramid shaped.
